(19) United States
(12) Patent Application Publication
(10) Pub. No.: US 2013/0147050 A1
(43) Pub. Date: Jun. 13, 2013

(54) SEMICONDUCTOR HAVING INTEGRALLY-FORMED ENHANCED THERMAL MANAGEMENT

(71) Applicants: Richard William Bonner, III, Lancaster, PA (US); Tapan Desai, Sinking Spring, PA (US)

(72) Inventors: Richard William Bonner, III, Lancaster, PA (US); Tapan Desai, Sinking Spring, PA (US)

(73) Assignee: ADVANCED COOLING TECHNOLOGIES, INC., Lancaster, PA (US)

(21) Appl. No.: 13/316,906

(22) Filed: Dec. 12, 2011

(51) Int. Cl. H01L 23/488; H01L 21/50

(52) U.S. Cl. 257/773; 438/106; 257/E21.499; 257/E23.023

(57) ABSTRACT

A semiconductor structure and method of manufacturing that has integrally-formed enhanced thermal management. During operation of a semiconductor device, electron flow between the source and the drain creates localized heat generation. A containment gap is formed by selectively removing a portion of the back side of the semiconductor device substrate directly adjacent to a localized heat generation area. A thermal management material is filled in the containment gap. This thermal management material enhances the thermal management of the semiconductor device by thermally coupling the localized heat generation area to a heat sink. The thermal management material may be a Phase Change Material (PCM) having a heat of fusion effective for absorbing heat generated in the localized heat generation area by the operation of the semiconductor device for reducing a peak operating temperature of the semiconductor device.

### BACKGROUND OF THE INVENTION

The present invention pertains to a semiconductor device having integrally-formed enhanced thermal management. Specifically, the present invention pertains to a semiconductor device, such as a gallium nitride transistor (GaN), that can be effectively formed on a substrate, such as silicon (Si), having integrally-formed enhanced thermal management so that transistors can be packed at higher device densities and operated at significantly higher power densities under pulsed operating conditions.

Recently, AlGaN/GaN high electron mobility transistors (HEMTs) have become a preferred option for solid-state amplifiers in the 1-40 GHz frequency range. With an output power density of more than 40 W/mm at 4 GHz, these devices offer an order of magnitude higher power density than Si-based electronics, higher efficiency levels, lower cooling requirements and easier impedance matching (U. K. Mishra, L. Shen, T. E. Kazior, and Y.-F. Wu, “GaN-based RF power devices and amplifiers,” Proc. Of the IEEE, vol. 96, no. 2, 287 (2008)). FIG. 1 is a cross section illustrating a conventional GaN-on-SiC HEMT. An HEMT is a semiconductor device that includes a source 10, gate 12 and drain 14 typically formed on a silicon carbide (SiC) substrate 16. The semiconductor layers include a GaN buffer 18, AlGaN barrier 20 and a GaN cap 22. A SiN passivation layer 24 protects the semiconductor device. During operation, electrons flowing through the semiconductor materials creating a localized heat generation zone 26. Conventionally, heat energy from the localized heat generation zone 26 is conducted through the SiC substrate 16 and removed via a heat sink 28.

The extremely high power densities available in nitride devices create new challenges for heat management and extraction on these devices. Most GaN transistors are grown on SiC substrates, which depending on the crystalline structure, can be between 1.5 and 3 times more thermally conductive than Si. However, this approach is not ideal. SiC substrates are typically only available on 4″ diameters, are many times more expensive than Si, and are still severely limit by heat dissipation. In addition, in spite of the unprecedented power densities demonstrated in these devices, commercial GaN devices typically operate at much lower power densities (4-6 W/mm) due to the great difficulty in dissipating the generated waste heat. The device junction temperature needs to be maintained below the maximum junction temperature of the device to minimize degradation in the transport properties of the semiconductor and, more importantly, to assure good reliability. Even when operating at the relatively low power densities of 4 W/mm, for proper operation these devices need to be attached to large heat sinks, appreciably limiting the system scalability and effective packaging.

In a semiconductor device, such as a pulse driven GaN transistor, heat is generated at discrete locations due to the electrical resistance faced by current as it traverses from source to drain circuitry, with the heat generation slightly favoring the drain side. FIG. 2 depicts heat generation within a GaN semiconductor. The dashed-line 30 shows the flow of electrons from the source 10 to the drain 14 that creates the localized heat zone 26. The heat flux generated from these individual transistors must then conduct through multiple layers of various metals, interface materials, etc. in what is commonly known as the thermal stack-up. Each layer adds to the overall thermal resistance of the device, resulting in increased peak junction temperatures. In a typical stack-up, the heat conduction path from the chip to the heat sink is as follows: chip→solder→tab→epoxy→metal baseplate→thermal interface material (TIM)→heat sink. Towards the heat sink end of the stack-up, the transient pulses of the pulse driven semiconductor devices at the chip level are not observed as the millisecond pulses of the driving signal but are instead dampened by the mass of the thick materials in the stack-up. Temperature profiles over a few duty cycles from an FEA analysis for a typical T/R device stack-up are displayed in FIG. 3, as described in S. Boslet, R. M. Morales, “Thermal Modeling Approaches for GaAS Semiconductors”, Electronics Cooling, February 2008.

During pulsed device operation, the GaN material at the chip level rapidly rises in temperature, as its low mass is not able to absorb the generated heat. Other materials farther from the chip have enough thermal capacitance to absorb the heat without requiring a large increase in temperature. These members of the thermal stack-up are only affected by the average power dissipated by the chip. Average power is determined by multiplying the duty cycle by the peak power. As shown in FIG. 3, fast increases and decreases in temperature are generally observed near the chip level, especially at the features of the chip very near the p-n junctions, with 50° C. swings in peak junction temperature being common.

A low resistance heat sink may help reduce peak junction temperature, but it will not reduce the magnitude of the chip level transient where the majority of the thermal problem resides. One common solution is to increase the thermal conductivity of materials that are located closely to the GaN device. SiC is typically used over Si because of its superior thermal conductivity. However, use of this material and others is often costly and impedes chip manufacturability because these materials are expensive and difficult to work with.

One way to increase the thermal storage of a material is to take advantage of the heat of fusion in the freeze/thaw cycles of a Phase Change Material (PCM). The volumetric heat storage capabilities can be increased an order of magnitude using the latent heat of fusion as compared to conventional materials used for heat sinking. The melting point of the PCM creates a “stop” for the peak junction temperature provided there is enough material to absorb all of the heat in the pulse and enough inactive time to release the heat and refreeze the PCM. An optimal amount of PCM will also keep the chip temperature from falling rapidly, which isothermalizes the chip over the entire duty cycle. Maintaining a constant temperature is ideal in terms of increasing reliability.

U.S. Pat. No. 6,848,500, issued to Langari et al., teaches an apparatus for reducing peak temperatures and thermal excursions of semiconductor devices such as those used in pulsed power applications. A PCM is thermally coupled to a semiconductor device. When the semiconductor device heats up during operation, the PCM absorbs the heat and melts, staying at a constant temperature during its phase change from solid to liquid. The PCM melting point is chosen to be just below the peak temperature that the semiconductor device would achieve if it were not thermally coupled with the PCM. When the semiconductor device approaches the maximum temperature, the PCM draws excess heat from the semiconductor devices and melts, thereby lowering the peak temperature of the semiconductor device. As the semiconductor device stops operating, heating stops and the PCM solidifies releasing the absorbed heat. This freezing and melting cycle of the PCM reduces the thermal stress experienced by the semiconductor device during its operation. FIG. 4 is an illustration showing this prior art PCM heat sink 32. PCM 32 is applied as a single piece of material either over the semiconductor devices or on the backside of the substrate on which the semiconductor devices are formed. A large scale groove may be formed in the substrate to hold the PCM 32.

U.S. Pat. No. 6,586,847, issued to Langari et al., teaches the use of a carbon-polymer deposited on top of an interconnect metal line in a semiconductor die. The polymer acts as a cushion to dampen temperature excursions of a pulsed semiconductor device. The polymer melts to absorb the heat generated by the semiconductor die, then re-freezes during the time when no waste heat is being dissipated in the semiconductor die. By this melting and refreezing of the polymer, the range of temperature excursions in the semiconductor die is reduced.

In accordance with the prior art, PCM is placed within the package such that the PCM basically covers the whole back or front side of the package. A common PCM well covers all of the transistors (which may number in the millions or even billions) in the package. Further, the PCM is located at the substrate level, which is on the order of 100's of microns away from the heat generating transistors.

In order to achieve effective thermal management for GaN transistors, it is desirable to dispose a thermal management material, such as a PCM, as close as possible to the source of localized heat within the transistor structure, namely, the location where electrons flow through the p and n material located between the source and the drain of the transistor. It would also be desirable to thermally couple the source of localized heat with a heat sink that is sufficiently constructed to remove heat away from the transistor during operation.

### SUMMARY OF THE INVENTION

The present invention is intended to provide a remedy by creating a semiconductor structure and method of manufacturing that has integrally-formed enhanced thermal management.

In accordance with the present invention, a substrate is provided having a front side and a back side. The substrate has a relatively low thermal capacitance. A semiconductor device is formed on the front side of the substrate. The semiconductor device has at least one p-n junction between which electrons flow during the operation of the semiconductor device. The electron flow creates a localized heat generation area located between the source and the drain. Heat typically conducts from the junction, through the semiconductor substrate, to a heat sink (usually metallic) mechanically attached to the back side of the substrate.

To create the enhanced thermal management structure, in accordance with the present invention, a containment gap is formed by selectively removing a portion of the back side of the substrate directly adjacent to the localized heat generation area. A supporting substrate structure is left behind under the semiconductor device. The supporting substrate structure supports the semiconductor device on the semiconductor device side of the containment gap and may also support a heat sink on the heat sink side of the containment gap. The containment gap is formed by selectively etching directly under the localized heat generation area in the back side of the substrate after the formation of the semiconductor device on the front side of the substrate.

A thermal management material having a relatively high thermal capacitance is filled in the containment gap. This thermal management material enhances the thermal management of the semiconductor device by thermally coupling the localized heat generation area to the material in the containment gap which has a high heat storage capacity. This allows the semiconductor to safely release more heat when operating under pulsed conditions while remaining below the maximum allowable junction temperature of the device.

The thermal management material can comprise a phase change material (PCM) having a heat of fusion effective for absorbing heat generated in the localized heat generation area by the pulsed operation of the semiconductor device for reducing a peak operating temperature of the semiconductor device. It is desirable that the PCM have high thermal conductivity, high heat of fusion, melting point below the maximum allowable junction temperature of the semiconductor device, and be capable of undergoing many cycles without degradation. Suitable materials include paraffin waxes, solders, salt hydrates, sugar and sugar derivatives (such as erythritol), and ice/water.

In accordance with another aspect of the present invention, a method is provided for making a semiconductor device having integrally-formed enhanced thermal management. A substrate is provided having a front side and a back side. The substrate has a relatively low thermal capacitance. A semiconductor device is formed on the front side of the substrate. The semiconductor device has at least one p-n junction between which electrons flow during the operation of the semiconductor device. The electron flow creates a localized heat generation area located between the source and the drain. A heat sink may be attached to the back side of the device for removing heat from the back side of the substrate. A containment gap is formed by selectively removing a portion of the back side of the substrate directly adjacent to the localized heat generation area while leaving a supporting substrate structure under the semiconductor device. The supporting structure supports the semiconductor device on the semiconductor device side of the containment gap. The supporting structure may also support the heat sink on a heat sink side of the containment gap. The containment gap is filled with a thermal management material having a relatively high thermal capacitance to enhance the thermal management of the semiconductor device by thermally coupling the localized heat generation area to the thermal management material. Ideally, only enough material is removed so that the size of the containment gap is optimized to hold no more than the amount of PCM required to effect the desired thermal management enhancement. For example, since the substrate may be more thermally conductive than the PCM, it is desired that the containment gap be dimensioned so that the amount of PCM it holds is about equal to the amount of PCM that will melt during the pulse operation of the semiconductor device.

### BRIEF DESCRIPTION OF THE DRAWINGS

FIG. 1 is a cross section illustrating a conventional GaN HEMT;

FIG. 2 is a schematic illustration showing in detail heat generation within a GaN chip;

FIG. 3 illustrates a temperature profile in a GaN chip stackup;

FIG. 4 is an illustration showing a prior art PCM heat sink

FIG. 5 illustrates the transient temperature gradients expected within a GaN chip that has embedded PCM in accordance with the present invention;

FIG. 6 is a cross section illustrating the inventive semiconductor device having integrally-formed enhanced thermal management;

FIG. 7 is a cross section illustrating a plurality of semiconductor devices formed on a common substrate and thermally coupled through the inventive integrally-formed enhanced thermal management structure to a common heat sink;

FIG. 8 illustrates the inventive chip level PCM technology;

FIG. 9 illustrates the steps for the fabricating GaN HEMTs having Si microchannels in accordance with the present invention;

FIG. 10 illustrates a large aspect ratio groove fabricated on a Si substrate of a GaN-on-Si HEMT in accordance with the present invention:

FIG. 11 illustrates several inventive shapes of the grooves;

FIG. 12 illustrates several inventive patterns of the grooves; and

FIG. 13 illustrates the inventive PCM heat sink having localized areas of PCM situated in close proximity to the heat generating junction.

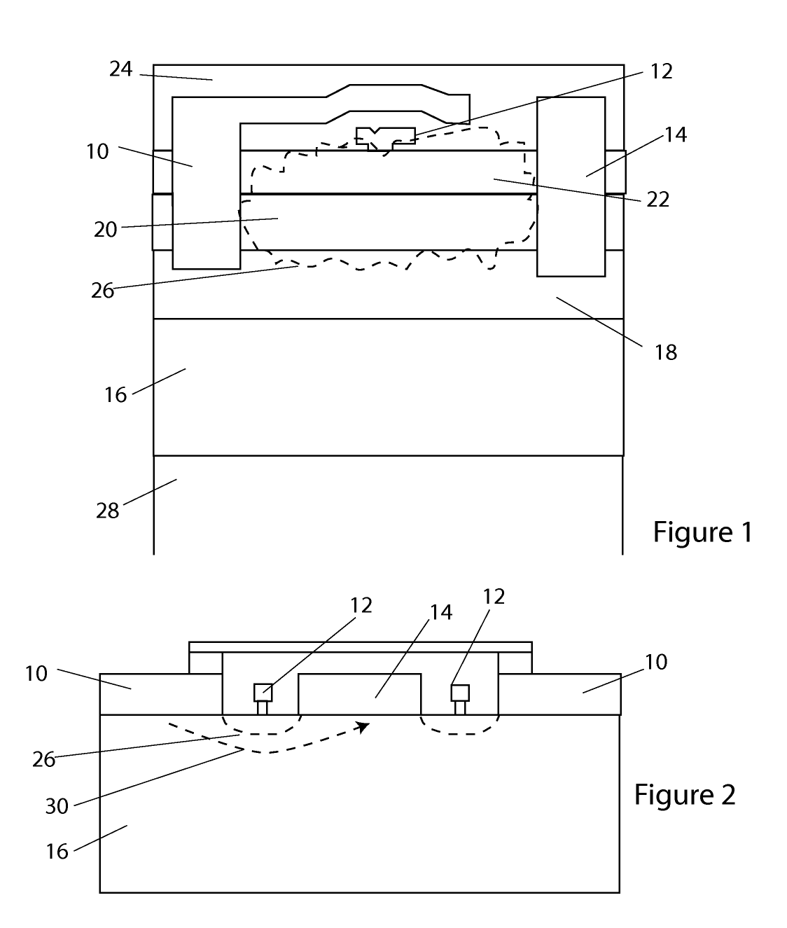

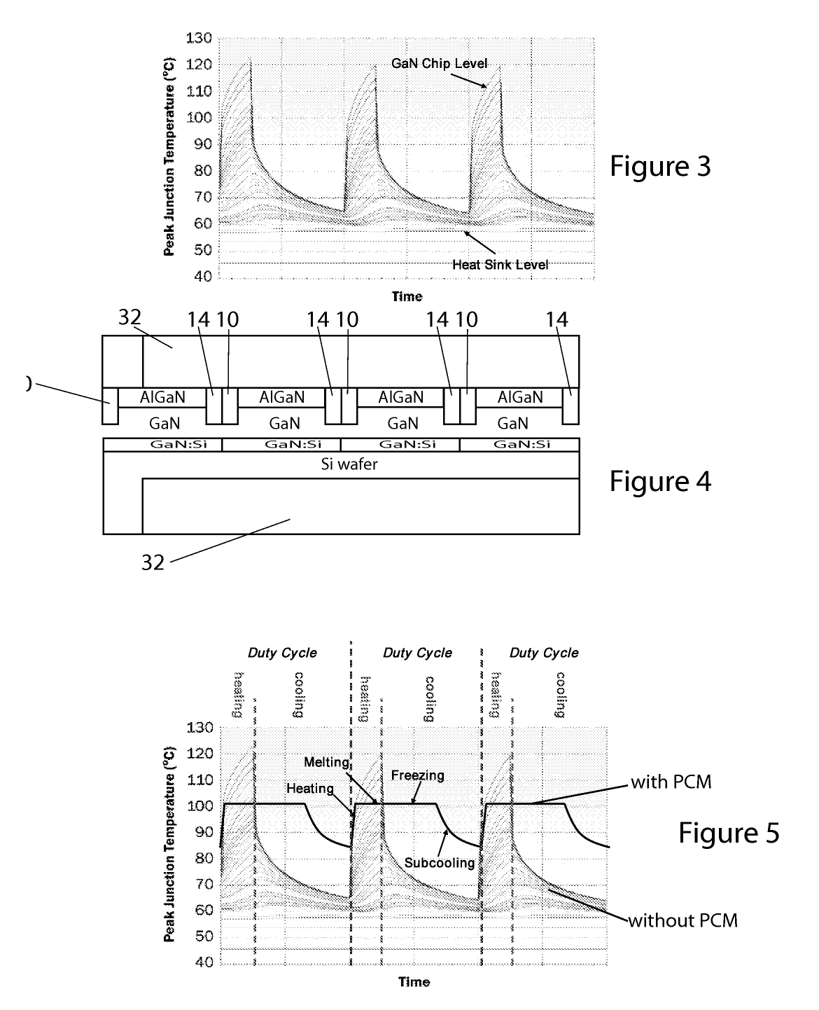

### DETAILED DESCRIPTION OF THE INVENTION

For purposes of promoting an understanding of the principles of the invention, reference will now be made to the embodiments illustrated in the drawings and specific language will be used to describe the same. It will nevertheless be understood that no limitation of the scope of the invention is thereby intended, there being contemplated such alterations and modifications of the illustrated device, and such further applications of the principles of the invention as disclosed herein, as would normally occur to one skilled in the art to which the invention pertains.

In accordance with the present invention, a phase change material (PCM) is disposed immediately adjacent to the source of heat in an operating semiconductor device, such as the location between the source and drain of a GaN transistor. The PCM is utilized to reduce the junction temperature and stabilize the operating temperatures in pulsed GaN devices by absorbing the rapid temperature transients observed in GaN transistors over each duty cycle. These transients can be reduced by increasing the effective heat capacity of materials close to the junction. In accordance with the present invention, the heat of fusion in freeze/thaw cycles of the PCM are utilized to absorb and stabilize the heat experienced at the location between the source and drain. The inventive structure places the PCM in very close proximity to the source of heat. The volumetric heat storage capabilities can be increased significantly by advantageously utilizing the latent heat of fusion of the PCM. A predetermined amount of PCM is provided directly adjacent to the source and drain location of the transistor, and the melting point of the PCM creates a “stop” for the peak junction temperature by absorbing the heat generated during a duty cycle pulse.

A PCM is a substance with a high heat of fusion, through melting and solidifying at a predetermined temperature, it is capable of storing and releasing large amounts of thermal energy. An expected transient temperature gradient within a GaN chip under pulsed operation that is modified with a PCM local to the junction is illustrated in FIG. 5. During the active time of each duty cycle, the large amount of heat generated by the GaN transistor will quickly heat up the solid-state PCM to its melting temperature. Heat will then be absorbed in the heat of fusion of the PCM as solid is converted to liquid. This will occur at constant temperature, equal to the melting point of the PCM. When the heating cycle is finished, the PCM will release the heat to the heat sink as it solidifies. When all the PCM becomes solid, it will subcool until the next cycle begins. The transient response depends strongly on the amount of PCM material, its proximity to the source of heat in the device, and melting point of the chosen PCM.

PCM is typically used in applications that require storage of large amounts of heat such as day/night cycles, directed energy applications (a few minutes), etc. The amount of PCM required is very large to accommodate this amount of heat and for many military and satellite applications the amount of required PCM can significantly affect the mass of the system. In accordance with the present invention, chip level cooling is achieved in which the transients are very small, with frequencies ranging from a fraction of a second to microseconds. Since only a small amount of PCM is required for this application, integration of PCM into the device at the source/drain feature level is feasible. The PCM melts to store heat during operation and refreezes to release heat to the heat sink.

FIG. 5 illustrates the transient temperature gradients expected within a GaN chip fabricated on a Si substrate that has embedded PCM utilized as a thermal management material in accordance with the present invention. GaN devices are typically fabricated on SiC devices due to its higher thermal conductivity. A GaN device on silicon would be preferred because silicon has the advantage of being lower cost than silicon carbide. Silicon is also easier to work with than silicon carbide, and more feasible for the manufacturing techniques required to create the inventive structure. The use of Si substrates allows a substantial reduction in wafer cost, more scalability to larger wafer diameters and more feasible fabrication of the containment gap structure.

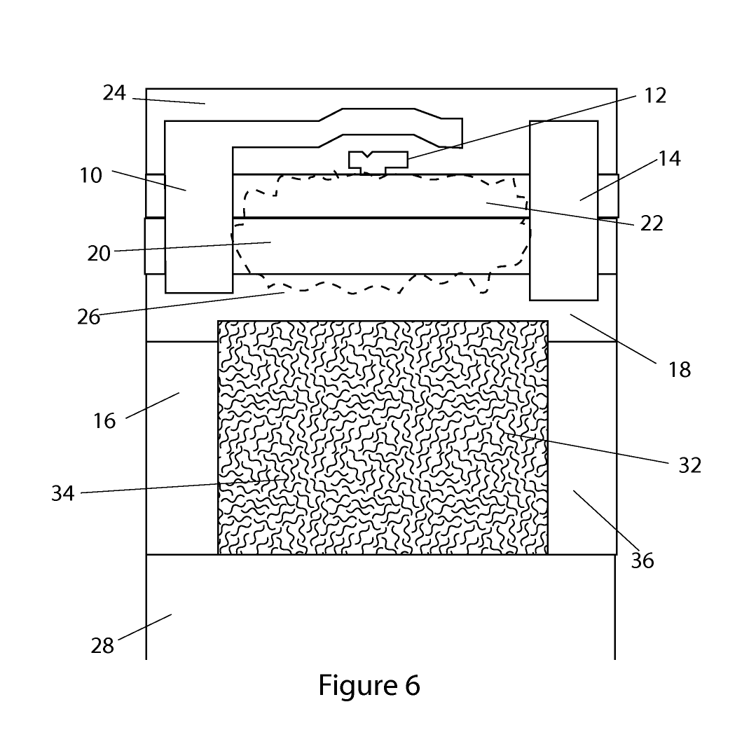

FIG. 6 is a cross section illustrating the inventive semiconductor device having integrally-formed enhanced thermal management. In accordance with the present invention, a Si substrate 16 is provided having a front side and a back side. Although Si is a relatively lower cost and easier to work with than SiC, the Si substrate 16 has a relatively low thermal conductivity. A semiconductor device is formed on the front side of the substrate 16. A GaN-on-Si HEMT having a source 10, gate 12 and drain 14 is illustrated as the semiconductor device. The semiconductor device has at least one p-n junction formed in the semiconductor layers between which electrons flow during the operation of the semiconductor device. The semiconductor layers include a GaN buffer 18, AlGaN barrier 20 and a GaN cap 22 The electron flow creates a localized heat generation area 26 26 located between the source 10 and the drain 14.

A containment gap 34 is formed by selectively removing portions of the back side of the substrate 16 directly adjacent to the localized heat generation area 26. This selective removal can be achieved, for example, through an etching operation. A supporting substrate structure 36 is left behind. The supporting substrate structure 36 supports the semiconductor device on semiconductor device side of the containment gap 34 and supports the heat sink 28 on a heat sink side of the containment gap 34. The containment gap 34 is formed by selectively etching directly under the localized heat generation area 26 from the back side of the substrate 16 after the formation of the semiconductor device on the front side of the substrate 16. As shown, the etching of the containment gap 34 is done at the semiconductor device feature level resolution (the location between the source 10 and the drain 14) and removes a portion of the Si substrate 16, and in the same or a subsequent etching operation, a portion of the GaN buffer 18 layer of the semiconductor device may also be removed, so that the PCM 32 can be filled into the containment gap 34 and come into very close proximity with the source 10 of the heat that is to be absorbed by the PCM 32 during the operation of the semiconductor device.

After forming the containment gap 34, it is filled with a thermal management material (PCM 32) having a relatively high thermal capacitance as compared with the SI substrate 16, which has a relatively thermal capacitance.

Selection of the PCM 32 is based on several criteria, the appropriate phase change temperature, the latent heat of fusion, low expansion rate, cycle life, electrical interference, chemical compatibility, surface tension, etc. The PCM 32 has a heat of fusion effective for absorbing heat generated in the localized heat generation area 26 during the operation of the semiconductor device and thereby reduces the peak operating temperature of the semiconductor device. The PCM 32 may be a solder having high thermal conductivity and a melting point below the allowed operating temperature of the p-n junction of the semiconductor device.

The semiconductor device can be a GaN transistor, such as a high electron mobility transistor (HEMT), which may be operated with a pulsed duty cycle. In order to provide improved operation of the transistor, the composition of the PCM 32 is selected to maintain an operating temperature of below 175 C at the p-n junctions of the semiconductor device. Because of the effectiveness of the inventive enhanced thermal management structure, Si may be effectively utilized as a substrate 16 material on which is formed the GaN transistor.

The dimensions of the heat sink, the containment gap 34 and the composition of the PCM 32 can be selected depending on the type of semiconductor device and operating condition being used. As an example, for a GaN transistor, the dimensions and composition can be optimized to transfer heat generated by the semiconductor device having a power density of greater than 4 watts/mm while maintaining a temperature of below 175 C at the p-n junction. The inventive thermal management structure may be used with other semiconductor devices, including but not limited to DIAC, diode, Gunn diode, IMPATT diode, laser, diode, LED, photocell, PIN diode, Schottky diode, solar cell, tunnel diode, VCSEL, VECSEL, Zener diode, Transistor, bipolar transistor, Darlington transistor, field-effect transistor, MOSFET, IGBT transistor, silicon controlled rectifier, thyristor, TRIAC, unijunction transistor, Hall effect sensor, IC, CCD, microprocessor, RAM and ROM. Substrates on which the semiconductor device may be formed include, but are not limited to Si, SiC, Silicon on Insulator, GaAs, GaN, CdSe, CdTe, CdHgTe, and ZnS.

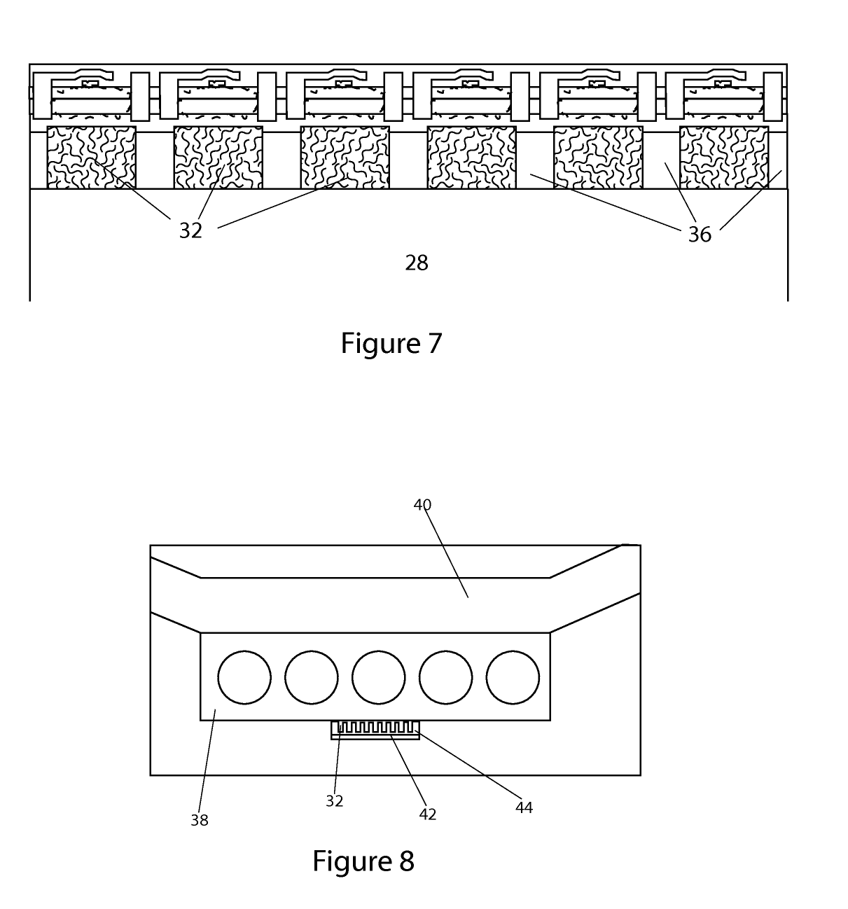

FIG. 7 is a cross section illustrating a plurality of semiconductor devices formed on a common substrate 16 and thermally coupled through the inventive integrally-formed enhanced thermal management structure to a common heat sink. Each semiconductor device has a containment gap 34 associated with it formed on the common Si substrate 16. Also, each semiconductor device is supported by the substrate 16 support structure that is not removed when the containment gap 34 is formed. By this construction, a plurality of semiconductor devices can be manufactured at the wafer level each with an integrally-formed enhanced thermal management structure. Alternatively, instead of each semiconductor device having a respective containment gap 34, a plurality of semiconductor devices can share the same containment gap 34 filled with a commonly shared PCM 32 acting to provide enhanced thermal management for the plurality of semiconductor devices.

As shown in FIG. 8, the heat sink may comprise a heat pipe 38 having a heat spreader fixed to the supporting substrate structure 36. The heat spreader of the heat pipe 38 can be thermally connected to a liquid cooled plate 40 so that heat from the operation of the semiconductor device that is generated at the localized heat generation area 26 is thermally coupled through the thermal management material to the heat pipe 38 and transferred via the heat pipe 38 to the liquid cooled plate 40.

FIG. 8 illustrates the inventive chip level PCM technology (not to scale). The GaN device 42, which can be around 10 mm in length, is formed on the front side of the silicon substrate 16. To create the containment gap, several grooves 44 are fabricated on the Si substrate 16 using Si micro-fabrication techniques. The grooves 44 provide a high thermal conductivity path to isothermalize the PCM 32. The PCM 32 may be less thermally conductive than the materials forming the containment gapwall, such as the substrate material. By forming the containment gap 34 as microgrooves 44 with a large aspect ratio, the heat transfer into the PCM 32 is enhanced. This feature of having microgrooves 44 with a large aspect ratio helps to isothermalize the PCM 32. The PCM 32 is not as thermally conductive as some of the materials around it, such as the semiconductor structure. Therefore, although the PCM 32 can store more heat, some attention needs to paid to getting heat effectively into the PCM 32. Similar to the fins used to enhance heat transfer to air in the case of a conventional heat sink, the groove structure increases surface area contact with the PCM 32 and substrate groove structure. Stated otherwise, the grooved structure makes the PCM 32 more uniform in temperature by more effectively getting heat into it, thus minimizing thermal gradients in the PCM 32. In order to avoid thermal expansion issues during the freeze/thaw cycles of the PCM 32, the grooves may not be completely filled to allow for an expansion volume to accommodate expansion of the PCM 32.

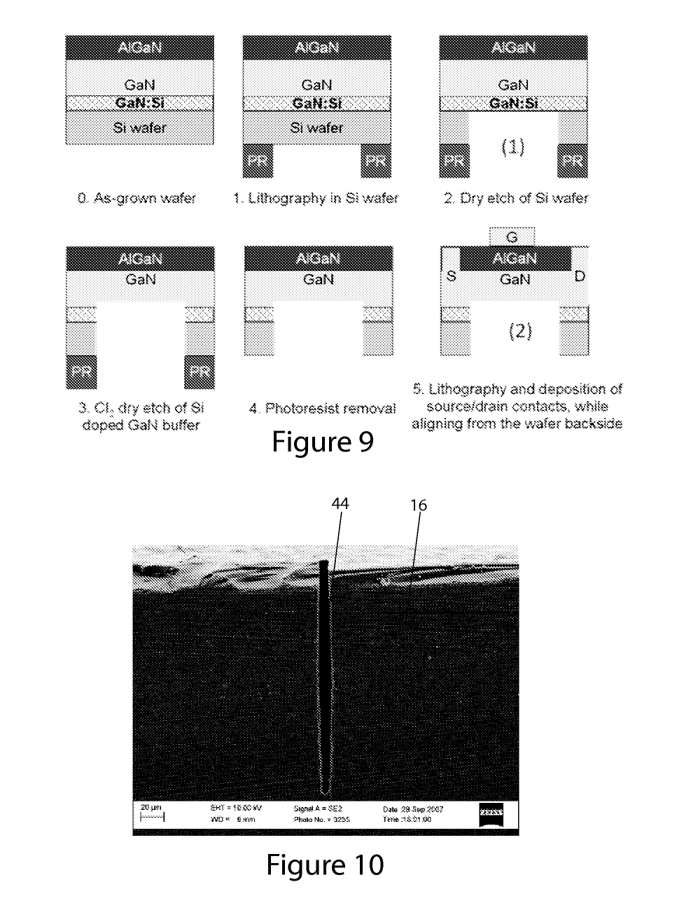

FIG. 9 illustrates the steps for the fabricating GaN HEMTs having Si micro-channels. In accordance with the present invention, the semiconductor device can be a GaN HEMT that includes a GaN buffer 18 layer formed between the substrate 16 and the localized heat generation area 26. The containment gap 34 may be formed only in the substrate 16, or it may include an area where a portion of the GaN buffer 18 layer is selectively removed after selectively removing the portion of the substrate 16. In this case, after the Si grooves have been fabricated, the GaN buffer 18 underneath them is thinned down to allow the PCM 32 to be as close as possible from the active device region, e.g., the localized heat generation area 26 between the source 10 and the drain 14 of a GaN transistor.

FIG. 10 illustrates a large aspect ratio groove 44 fabricated on a Si substrate 16 of a GaN-on-Si HEMT. The back side of the silicon substrate 16 can be mounted to a heat sink/heat spreader plate. The heat pipe plate spreads the heat out over a liquid cooled heat sink (alternatively, the heat sink can be air cooled).

To further improve performance of the inventive semiconductor device having integrally-formed enhanced thermal management, solder with a low melting point can be utilized as the PCM 32. Solders have the advantage over paraffin waxes and some of the other typical PCMs in that they have high thermal conductivity. For example, a Tin/Indium solder can be formulated with a melting point of 118° C. As an example, GaN semiconductor devices can be constructed in accordance with the present invention on a Si substrate dissipating 100 W/cm² (an aggressive assumption) during peak power over a 10 millisecond pulse, using a layer of approximately 32 microns of Tin/Indium solder to adsorb the heat generated during the operation of the GaN semiconductor devices.

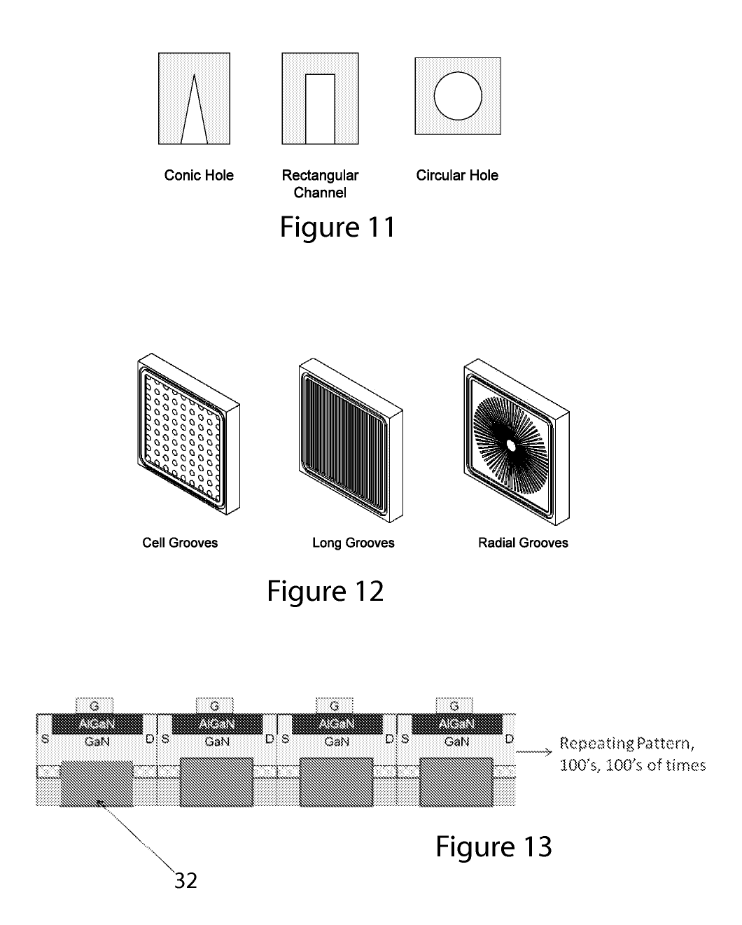

An appropriate structure for the grooves 44 in the device is important to the thermal performance and the structural performance (the grooves 44 must handle thermal stress generated by the expansion/contraction of solder during the freeze/thaw process). The containment gap 34 can be formed by microgrooves 44 selectively etched directly under the localized heat generation area 26 in the back side of the substrate 16 after the formation of the semiconductor device on the front side of the substrate 16. The microgrooves 44 can be formed having a large aspect ratio grooves having a width optimized for the transfer of heat between the localized heat generation area 26 and the heat sink. FIG. 10 illustrates a large aspect ratio groove 44 fabricated on a Si substrate 16 of a GaN-on-Si HEMT. FIG. 11 illustrates several potential shapes of the grooves 44. The microgrooves 44 may have at least one of a conic hole, rectangular channel and cylindrical cross-section. The microgrooves 44 can be a plurality of selectively etched grooves distributed as one of individual cylindrically-shaped cells, long parallel trenches or radial distributed micro-trenches. FIG. 12 illustrates several other potential patterns of grooves 44. The containment gap 34 can be formed as radially distributed microgrooves etched into the substrate 16, each groove emanating from a central location, the central location being located directly underneath the localized heat generation area 26.

As described above, FIG. 4 is an illustration showing a prior art PCM heat sink. In contrast, FIG. 13 illustrates the inventive PCM heat sink having localized areas of PCM 32 situated in much closer thermal proximity to the heat-generating p-n junctions of the semiconductor device than is achievable with the prior art PCM heat sink.

In accordance with an application of the present invention, multiple wells of PCM 32 are located to align with a set of transistors, with each set of transistors numbering from one to several thousand. In a complete package, there will likely be thousands, if not millions of PCM wells. The containment gaps 34 for the PCM 32 will be located on the side opposite of the devices and be integral to the substrate 16. Further, the grooved structure that holds the PCM 32 will also help conduct heat to the PCM 32 farthest from the active transistors, similar to fins in a traditional heat sink. Each PCM well (containment gap 34) is in closer proximity (exceeding 100 times closer) than the previous art. In other words, the PCM wells are within 1-10 microns of the active transistors and inducing junction-level cooling.

The inventive enhanced thermal management structure makes it feasible to construct relatively high power semiconductor devices, such as GaN HMETs on a relatively low cost, easier to work, relatively low thermally conductive substrate, such as Si. In accordance with the present invention, multiple GaN HEMT devices are formed simultaneously on a common Si substrate 16. Each HEMT is thermally coupled through the inventive integrally-formed enhanced thermal management structure to a common heat sink. Each HEMT has a containment gap 34 associated with it formed on the common Si substrate 16 and is supported by the substrate support structure 36 that is not removed when the containment gap 34 is formed. By this construction, a plurality of semiconductor devices can be manufactured at the wafer level each with an integrally-formed enhanced thermal management structure. As an alternative, two or more neighboring semiconductor devices can be associated with a common containment gap 34 and PCM well. In this case, the dimensions of the containment gap 34 and the left behind substrate support structure 36, as well as the composition of the PCM 32, is selected so that the overall integrity and function of the semiconductor/thermal management/substrate/heat sink system is optimized in terms of performance and costs.

With respect to the above description, it is realized that the optimum dimensional relationships for parts of the invention, including variations in size, materials, shape, form, function, and manner of operation, assembly and use, are deemed readily apparent and obvious to one skilled in the art. All equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described. Accordingly, all suitable modifications and equivalents may be resorted to, falling within the scope of the invention.

1. A semiconductor device package having integrally-formed enhanced thermal management, comprising:
a substrate having a front side and a back side;
a semiconductor device formed on the front side of the substrate, the semiconductor device having at least one p-n junction between which electrons flow during the pulsed operation of the semiconductor device, the electron flow creating a localized heat generation area;
a containment gap formed by selectively removing a portion of the back side of the substrate directly adjacent to the localized heat generation area while leaving supporting substrate structure for supporting the semiconductor device on the front side of the substrate;
and a thermal management material having a relatively high thermal capacitance filled in the containment gap and thermally coupled to the localized heat generation area to enhance the thermal management of the semiconductor device, the thermal management material comprising a Phase Change Material (PCM) having a heat of fusion effective for absorbing heat generated in the localized heat generation area by the operation of the semiconductor device for reducing a peak operating temperature of the semiconductor device, the composition of the PCM being effective to maintain an operating temperature below a predetermined maximum specified temperature at the p-n junction of the semiconductor device.

2. A semiconductor device package according to claim 1; wherein the PCM is a metallic solder having high thermal conductivity and a melting point below the recommended or allowed operating temperature of the p-n junction of the semiconductor device.

3. A semiconductor device package according to claim 1; wherein a buffer layer is formed between the substrate and the localized heat generation area;
and wherein the containment gap includes an area where a portion of the buffer layer is selectively removed after selectively removing the portion of the substrate.

4. A semiconductor device package according to claim 1; wherein the PCM comprises at least one of a paraffin wax, solder, salt hydrate, sugar and sugar derivative.

5. A semiconductor device package according to claim 1; wherein the semiconductor device is a device that is selected from a list that includes but is not limited to a transistor, DIAC, diode, Gunn diode, IMPATT diode, laser, diode, LED, photocell, PIN diode, Schottky diode, solar cell, tunnel diode, VCSEL, VECSEL, Zener diode, Transistor, bipolar transistor, Darlington transistor, field-effect transistor, MOSFET, IGBT transistor, silicon controlled rectifier, thyristor, TRIAC, unijunction transistor, Hall effect sensor, IC, CCD, microprocessor, RAM and ROM; and wherein the substrate is selected from a list that includes but is not limited to Si, SiC, Silicon on Insulator, GaAs, GaN, CdSe, CdTe, CdHgTe, and ZnS.

6. A semiconductor device package according to claim 1; wherein the containment gap is formed by microgrooves selectively etched under the localized heat generation area in the back side of the substrate after the formation of the semiconductor device on the front side of the substrate.

7. A semiconductor device package according to claim 6; wherein the microgrooves have at least one of a conic hole, rectangular channel and cylindrical cross-section.

8. A semiconductor device package according to claim 6; wherein the microgrooves are a plurality of selectively etched grooves distributed as one of individual cylindrically shaped cells, long parallel trenches or radial distributed micro-trenches.

9. A semiconductor device package according to claim 6; wherein the microgrooves are large aspect ratio grooves having a width optimized for the transfer of heat between the localized heat generation area and the PCM.

10. A semiconductor device package according to claim 1; wherein the containment gap is formed as radially distributed microgrooves etched into the substrate, each groove emanating from a central location, the central location being located directly underneath the localized heat generation area.

11. (canceled)

12. (canceled)

13. (canceled)

14. (canceled)

15. (canceled)

16. (canceled)

17. (canceled)
